(19) United States
(12) Patent Application Publication
(10) Pub. No.: US 2021/0302619 A1
(43) Pub. Date: Sep. 30, 2021

(54) WELLBORE QUALITY IMPROVEMENT

(71) Applicant: Saudi Arabian Oil Company, Dhahran (SA)

(72) Inventors: Adel Ali Al-Qahtani, Khobar (SA); Osman Hamid, Houston, TX (US); Khaqan Khan, Dhahran (SA); Waheed Arshad, Dhahran (SA)

(21) Appl. No.: 16/828,730

(22) Filed: Mar. 24, 2020

(51) Int. Cl. G01V 99/00; E21B 44/00; E21B 47/022; G06F 30/20

(52) U.S. Cl. CPC G01V 99/005; G06F 30/20; E21B 47/022; E21B 44/00

(57) ABSTRACT

A computer system receives data representing a hydrocarbon reservoir. The data includes a surface location, reservoir property data, mechanical property data, and offset well information of the hydrocarbon reservoir. The computer system generates a three-dimensional (3D) geomechanical model of the hydrocarbon reservoir based on the data. The 3D geomechanical model is for identifying a sweet spot in the hydrocarbon reservoir for drilling and stimulation, and placing a hydrocarbon well in the sweet spot. The computer system determines drilling parameters based on the 3D geomechanical model and the offset well information. The drilling parameters are to reduce an enlargement of a wellbore of the hydrocarbon well. The computer system monitors the drilling parameters until the hydrocarbon well reaches a particular depth from a surface of the Earth. The computer system performs a rigless operation on the hydrocarbon well.

### TECHNICAL FIELD

This description relates generally to hydrocarbon wells, for example, to wellbore quality improvement.

### BACKGROUND

Hydrocarbon well drilling can pose several challenges. Drilling in locations where formations are nonhomogeneous can lead to problems. The problems encountered during the drilling of hydrocarbon wells can increase cost. Drilling problems can include pipe sticking, lost circulation, hole deviation, pipe failures, borehole instability, mud contamination, formation damage, and hole cleaning.

### SUMMARY

Methods, apparatus, and systems for wellbore quality improvement are disclosed. A computer system receives data representing a hydrocarbon reservoir. The data includes geological data, geophysical data, reservoir property data, mechanical property data, and offset well information of the hydrocarbon reservoir. The computer system generates a three-dimensional (3D) geomechanical model of the hydrocarbon reservoir based on the data. The 3D geomechanical model is for identifying a sweet spot in the hydrocarbon reservoir for drilling, production, and stimulation, and placing a hydrocarbon well in the sweet spot. The computer system determines a geomechanical quality index using porosity, permeability, gas saturation, mechanical properties, and reservoir stress of the hydrocarbon reservoir. The computer system determines a mud weight based on the 3D geomechanical model. The mud weight is to control the wellbore stability and reduce an enlargement of a wellbore of the hydrocarbon well. The computer system determines a rate of penetration (ROP), a drilling flow rate, and a revolutions-per-minute (RPM) based on drilling parameters of offset wells. The drilling parameters are to control the wellbore stability and reduce the enlargement of the wellbore of the hydrocarbon well. The computer system monitors the drilling parameters while drilling until the hydrocarbon well reaches a particular depth from a surface of the Earth. The computer system calibrates the geomechanical model after drilling and stimulation operation completed by using drilling and stimulation data

In some implementations, the 3D geomechanical model includes a distribution of porosity, permeability, gas saturation, mechanical properties, and reservoir stress of the hydrocarbon reservoir across a 3D space.

In some implementations, the 3D geomechanical model includes a distribution of a geomechanical quality index determined using porosity, permeability, gas saturation, mechanical properties, and reservoir stress of the hydrocarbon reservoir across a 3D space.

In some implementations, the computer system determines a trajectory of the hydrocarbon well and an azimuth of the hydrocarbon well based on the 3D geomechanical model.

In some implementations, the computer system determines a mud weight, based on the 3D geomechanical model.

In some implementations, the drilling parameters of the hydrocarbon well include an ROP, an RPM and a flow rate.

In some implementations, the computer system monitors the drilling parameters of the hydrocarbon well while drilling until the hydrocarbon well reaches a particular depth from a surface of the Earth.

In some implementations, the computer system calibrates the geomechanical model after the drilling and stimulation operations are completed using second data obtained from the drilling and stimulation operations in the hydrocarbon well.

### BRIEF DESCRIPTION OF THE DRAWINGS

FIG. 1 illustrates a workflow for wellbore quality improvement.

FIG. 2 illustrates a three-dimensional (3D) geomechanical model.

FIG. 3 compares hole conditions with and without using the disclosed implementations.

FIG. 4 is a flowchart illustrating a process for wellbore quality improvement.

### DETAILED DESCRIPTION

The implementations disclosed provide methods, apparatus, and systems for wellbore quality improvement. The implementations enable the identification of “sweet spots” in a hydrocarbon reservoir, the planning of hydrocarbon well placement into the reservoir, and the determination of the well completion type. Wellbore washouts and breakouts are reduced, and the likelihood of successful deployment of the completion process is increased. The condition of the drilled hole and the well stimulation is improved, while operational time and effort are reduced, thus increasing operational efficiency.

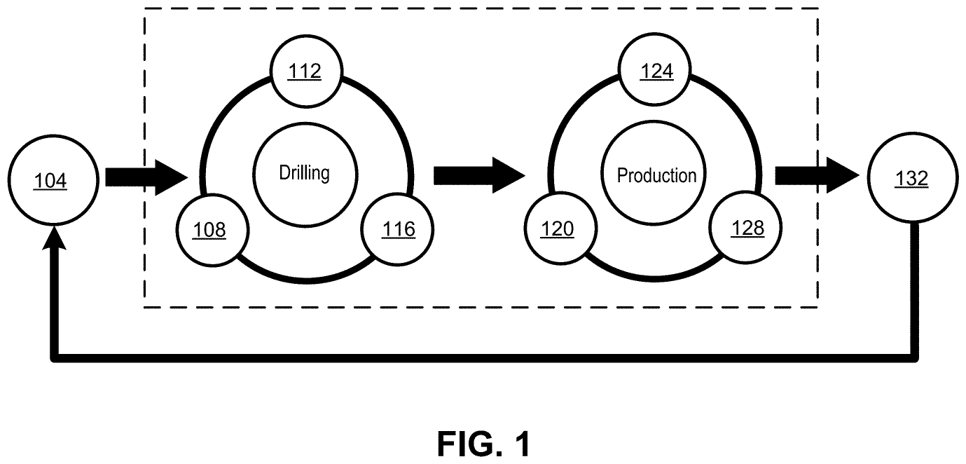

FIG. 1 illustrates a process for wellbore quality improvement while drilling a hydrocarbon well in a hydrocarbon reservoir. A hydrocarbon reservoir refers to a subsurface pool of hydrocarbons contained in porous or fractured rock formations. A hydrocarbon well refers to a boring in the Earth that is designed to bring petroleum oil hydrocarbons and natural gas to the surface. Multiple hydrocarbon wells can be bored in a reservoir. The process illustrated in FIG. 1 can be performed by more than one computer system.

Step 104 is sometimes referred to as a “Pre Well” step. Step 104 is performed at three months to a year prior to when the hydrocarbon well is spud. Spudding is the process of rigging up a rig site at the well location on the surface in order to start drilling the well. Step 104 typically takes three weeks to perform.

The computer system receives data representing the hydrocarbon reservoir. The data includes geological data, geophysical data, reservoir property data, mechanical property data, and offset well information of the hydrocarbon reservoir. The data can include the surface location of the planned hydrocarbon well. The surface location is expressed in X and Y coordinates that represent the X-value and the Y-value of the geomatic survey. During Step 104, particular functions of the hydrocarbon reservoir management, reservoir characterization, drilling engineering, and production engineering are performed, and parameters for drilling a new hydrocarbon well are determined. For example, steps for planning the hydrocarbon well can be performed, including a review of the surface location of the hydrocarbon reservoir and offset wells in terms of development. The computer system matches a target (the end point of the planned hydrocarbon well) with the surface location (the starting point of the well), and designs a trajectory between the two. An offset well refers to an existing wellbore used to perform the steps for planning the hydrocarbon well. Offset well development is used to identify subsurface geology and pressures. The offset well data can also be combined with seismic data by the computer system. The offset well data refers to the porosity, permeability, gas saturation, compressional velocity, and shear velocity obtained from the offset wells.

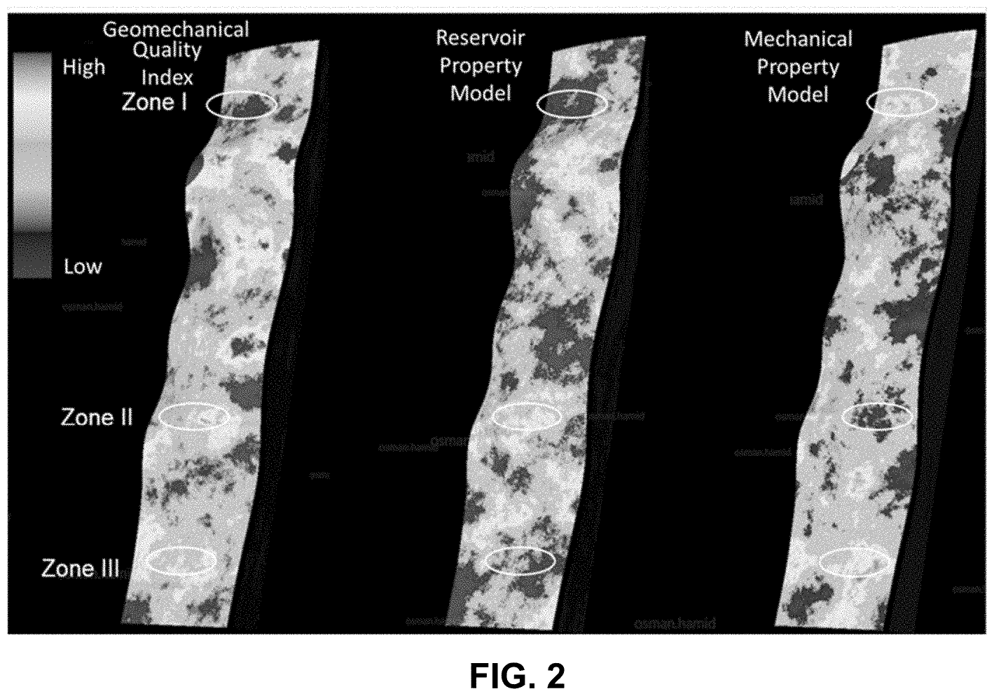

The computer system generates a three-dimensional (3D) reservoir model and mechanical model of the hydrocarbon reservoir based on the data representing the hydrocarbon reservoir. The computer system clusters the generated three-dimensional (3D) reservoir model and mechanical model and generates a three-dimensional (3D) geomechanical model. In some implementations, the 3D geomechanical model includes a distribution of a geomechanical quality index calculated using porosity, permeability, gas saturation, mechanical properties and reservoir stress of the hydrocarbon reservoir across a 3D space. An example 3D reservoir model, mechanical model, and geomechanical model is illustrated and described in more detail with reference to FIG. 2. The 3D geomechanical model is used to improve the placement of a hydrocarbon well in the hydrocarbon reservoir. For example, gas saturation, reservoir pressure, and stress are used to predict issues or risks that can arise while drilling or stimulation of the hydrocarbon well, such as shallow picks, uncertain formation dips, or washouts. A shallow pick refers to a top section of the hydrocarbon reservoir, but which contains no hydrocarbons or is nonproductive. An uncertain formation dip refers to an angle between a planar feature of the hydrocarbon reservoir , such as a sedimentary bed or a fault, and a horizontal plane that can impact drilling of the hydrocarbon well or hydrocarbon recovery. A washout refers to an enlargement of a wellbore and can be caused by unconsolidated formations, in-situ rock stresses, or weakening of shale as it contacts fresh water. An unconsolidated formation refers to a softer formation in the reservoir where the wellbore can collapse.

In some implementations, the computer system determines a trajectory of the hydrocarbon well and an azimuth of the hydrocarbon well based on the 3D geomechanical model. For example, the computer system analyzes the data from the offset wells development and generates a well trajectory, an azimuth, and an inclination for placement of the hydrocarbon well. The azimuth refers to a direction in which a horizontal hydrocarbon well is drilled relative to magnetic North. A horizontal well is an oil or gas well dug at an angle of at least eighty degrees to a vertical wellbore. For example, drilling of a horizontal well in a tight gas reservoir in a direction of reduced horizontal stress enables the generation of multiple hydraulic fractures that are normal to the wellbore. “Tight gas” sometimes refers to natural gas produced from reservoir rocks having permeability less than a threshold value. “Tight gas reservoirs” sometimes refer to reservoirs having permeability and porosity less than threshold values. The inclination refers to an angle of the deviation of a wellbore from the vertical path. The computer system determines a particular inclination for placing the hydrocarbon well based on the 3D geomechanical model for increasing an exposed section length through the hydrocarbon reservoir by drilling through the reservoir at a particular angle. The inclination can be from 45° to 90°. Determining an efficient inclination also enables drilling into locations where vertical access is difficult or not possible such as in oilfields underneath a town, lake or a in a difficult-to-drill formation. Moreover, an efficient inclination enables grouping more wellheads together on a surface location so as to allow fewer rig moves, less surface area disturbance, and make it easier and cheaper to complete and produce wells.

The computer system determines a placement of the hydrocarbon well within the hydrocarbon reservoir, based on the 3D geomechanical model, for improved geosteering. In some implementations, the geosteering improves placement of the wellbore based on real time downhole geological and geophysical logging measurements, such that the wellbore is placed within a hydrocarbon pay zone. In other implementations, during steps 108 and 112, geosteering is used to adjust the borehole position (inclination and azimuth angles) on the fly to reach one or more geological targets. The computer system also determines the best fit-for-purpose logging tools required for the hydrocarbon well after analysis of the offset well data. For example, the computer system determines the wellbore position needed for reservoir contact of the hydrocarbon well after analyzing the offset well data. The 3D geomechanical model is thus used to identify improved well placement for drilling and stimulation.

In some implementations, the data representing the hydrocarbon reservoir includes acoustic impedance measurements. The computer system characterizes in-situ stresses, and stratigraphic and structural elements based on the acoustic impedance measurements. The characterization of the in-situ stresses, and stratigraphic and structural elements is used to determine the well placement strategy. For example, to place the wellbore into a “sweet spot” in the hydrocarbon reservoir, the 3D geomechanical model is used to describe the state of stresses, mechanical properties, reservoir properties, formation pressures in the hydrocarbon reservoir and overburden. The objectives of the 3D modeling include the well placement in a “sweet spot” and obtaining guidance for drilling stability. For example, if a deviated or horizontal well is planned, the computer system determines a direction of the horizontal well. In a deviated well, a drill bit is deflected at an angle from the vertical toward a specific target. The computer system determines a position of potential hydro-fracking zones or areas. If multi-stage fracking treatments along a horizontal well will be performed, the computer system determines a direction of the horizontal well. The computer system determines, based on the 3D geomechanical model, parameters including an injection pressure and a state of stress as well as mechanical properties for hydraulic fracking zones and the adjacent formations for improved hydro-fracking. The computer system provides guidance for the pressure drawdown for a given well completion to avoid sand production. Pressure drawdown refers to a difference between the reservoir pressure and the flowing wellbore pressure that drives fluids from the reservoir into the wellbore. Pressure drawdown can impact the production rate of a well. Further, an optimal completion type (open hole or cased hole) and perforation is determined for a given pressure drawdown. Completion refers to making a well ready for production (or injection) after drilling, such as by preparing the bottom of the hole to the required specifications, running in the production tubing and its associated down hole tools, and perforating and stimulating as required.

Step 108 is sometimes referred to as a “Pre Drill” step. Step 108 is performed when the hydrocarbon well is spud, and typically takes three weeks to perform. Step 108 is the first stage in the drilling-completion phase. The computer system determines the parameters required for drilling, such that the hydrocarbon well has a stable and improved-quality wellbore to reduce drilling problems, acquire higher-quality logs, and successfully run multi-stage completions. For example, drilling a horizontal well towards a reduced horizontal stress direction in a strike slip stress environment, and having a hole condition suitable for running openhole multistage fracturing (MSF) completions can be important for reservoir development.

The computer determines a mud weight based on the 3D geomechanical model. Mud weight refers to a density of drilling fluid and is measured in pounds per gallon (ppg) or pound cubic feet (pcf). For example, a mud weight used can be 22 or 23 ppg. The determined mud weight is used to reduce an enlargement of a wellbore of the hydrocarbon well. For example, the mud weight is to control the wellbore stability and minimize an enlargement of a wellbore of the hydrocarbon well. The computer system determines the mud weight to reduce a severity of breakouts. Breakouts refer to stress-induced enlargements of the wellbore cross-section. In some implementations, the computer system determines a mud flow rate and a drilling revolutions-per-minute (RPM) based on the 3D geomechanical model and offset wells information. For example, the computer system can determine that drilling parameters , such as ROP, RPM and flow rate should be used to reduce enlargements of the wellbore cross-section.

The computer system determines drilling parameters (surface RPM and mud flow rates) to reduce post-drilling disturbance to the wellbore wall. A particular mud flow rate can also be required for carrying drill cuttings to the surface. The methods to address wellbore stability described here can have three main implementations, each allowing a different level of hole enlargement. In a first implementation (sometimes referred to as “wellbore stability for drilling”), the computer system performs geomechanical analysis for determining the mud weight and drilling parameters for mitigating drilling issues. The computer system increases the drilling efficiency by maintaining the wellbore stable (with no limit on the allowable hole enlargement), and enabling improved hole cleaning, which avoid drilling problems, such as tight hole, stuck pipe, pack off, and excessive reaming. A tight hole refers to a wellbore where larger-diameter components of the drillstring can experience resistance. A drillstring refers to a column of drill pipe that transmits drilling fluid (mud) and torque to the drill bit. A stuck pipe refers to one that is difficult to free from the hole without damaging the pipe. Pack off refers to the need to plug the wellbore around a drillstring because, for example, the drilling fluid is not properly transporting cuttings out of the annulus or a portion of the wellbore wall has collapsed.

In some implementations, the enlargement of the wellbore of the hydrocarbon well is in a range from 0.1 inches to 2 inches. For example, in a second implementation of the methods to address wellbore stability, the computer system limits approximately 90% of the hole enlargements to 1.5 inches in order to improve the reliability of acquired log data. The second implementation is targeted at vertical and deviated wells. In experiments performed on a number of hydrocarbon wells, the limits of mud overbalance and drilling parameters showed good results for wellbore stability. The good results refers to the outcomes when 90% of the hole enlargement is limited to 1.5 inches. In a third implementation of the methods to address wellbore stability, the computer system uses a more stringent criterion of 0.3-0.4 inches for the allowed hole enlargement. In the experiments conducted, the second implementation showed a trend of improving hole conditions. However, in some experiments, the third implementation produced better results for MSF, especially under conditions of tighter reservoirs (porosity<7%).

Step 112 is sometimes referred to as a “While Drill” step. Step 112 is performed beginning from when the reservoir section is or an overburden (sealing) formation is drilled until when the hydrocarbon well reaches a total depth. The overburden refers to the rock overlying an area or point of interest in the subsurface. The total depth refers to a bottom of the well (the depth where drilling has stopped). Step 112 is the second stage in the drilling-completion phase. In some implementations, the computer system monitors drilling parameters of the hydrocarbon well until the hydrocarbon well reaches a particular depth (target depth or total depth) from the surface of the Earth. In some implementations, the drilling parameters of the hydrocarbon well include a rate of penetration (ROP), the RPM, and a flow rate. The ROP refers to a speed at which the drill bit can break the rock and deepen the wellbore. The flow rate refers to a rate of fluid injection. The computer system monitors the mud weight and additional drilling parameters, such as reaming and drillstring vibration, using real time drilling data. Drillstring vibration can diminish the life of the wellbore by fatigue, and cause pipe failure, wash-outs, or decrease in the ROP. If logging while drilling (LWD) is used, the LWD data is also analyzed by the computer system in step 112. LWD refers to a technique of conveying well logging tools into the well borehole as part of the bottom hole assembly (BHA). The BHA refers to the lowest part of the drillstring, that extends from the drill bit to the drill pipe. The computer system receives and processes the real time data using correlations to the data from offset wells for benchmarking.

Step 116 is sometimes referred to as a “Post Drill” step. Step 116 is performed after the hydrocarbon well reaches the total depth, and typically takes two weeks to perform. Step 116 is the third stage in the drilling-completion phase. Step 116 is performed after reaching the target depth when the drilling rig starts pulling out from the borehole.

Step 120 is sometimes referred to as a “Pre Stim” step. Step 120 is performed while the requirements for stimulation of the hydrocarbon well are being met. The requirements refer to the scenario when the wellbore quality is good, for example, less than a 1.5 inches enlargement. Stimulation refers to an intervention performed on the hydrocarbon well to increase production by improving the flow of hydrocarbons from the drainage area into the well bore. Step 120 typically takes a week to perform. After step 116 is performed, step 120 begins the stimulation and production phase. Based on the borehole conditions, the computer system determines a best-fit completion type required for stimulation of the hydrocarbon well. The computer system also determines parameters for design ports and packer depths based on the logging results. Port depths refer to depths at which a formation is fracked or broken. Packer depths refer to depths at which packers are set to isolate between ports. For example, multiple packer systems having fracking ports can improve production, especially in the case of horizontal wells.

Step 124 is sometimes referred to as a “While Stim” step. Step 124 is performed when a rigless site is moved to the location of the hydrocarbon well and continues until the hydrocarbon well is flowed back. Flowback refers to the process of allowing fluids to flow from the hydrocarbon well following a treatment in preparation for returning the well to production. In some implementations, the computer system performs a rigless operation on the hydrocarbon well in step 124. Rigless operation refers to an intervention operation conducted using equipment and support facilities without requiring a rig over the wellbore. The rigless site can include coiled tubing or a slickline. The coiled tubing refers to a continuous length of pipe wound on a spool that is straightened prior to pushing into the wellbore and rewound to coil the pipe back onto the spool. The slickline refers to a nonelectric cable used for selective placement and retrieval of wellbore hardware, such as plugs, gauges, or valves. Step 124 is the second stage in the stimulation and production phase.

Step 128 is sometimes referred to as a “Post Stim” step. Step 128 is performed after the flowback process. Step 128 typically takes one week to perform. Step 128 is the third stage in the stimulation and production phase.

Step 132 is sometimes referred to as a “Post Well” step. Step 132 is performed two weeks after the rigless operation is completed. Step 132 typically takes three weeks to perform. Responsive to determining, by the computer system, that the rigless operation has completed, the computer system calibrates the 3D geomechanical model based on data obtained from the new hydrocarbon well. The new data includes values of porosity, permeability, compressional velocity, shear velocity, breakdown pressure, and reservoir pressure.

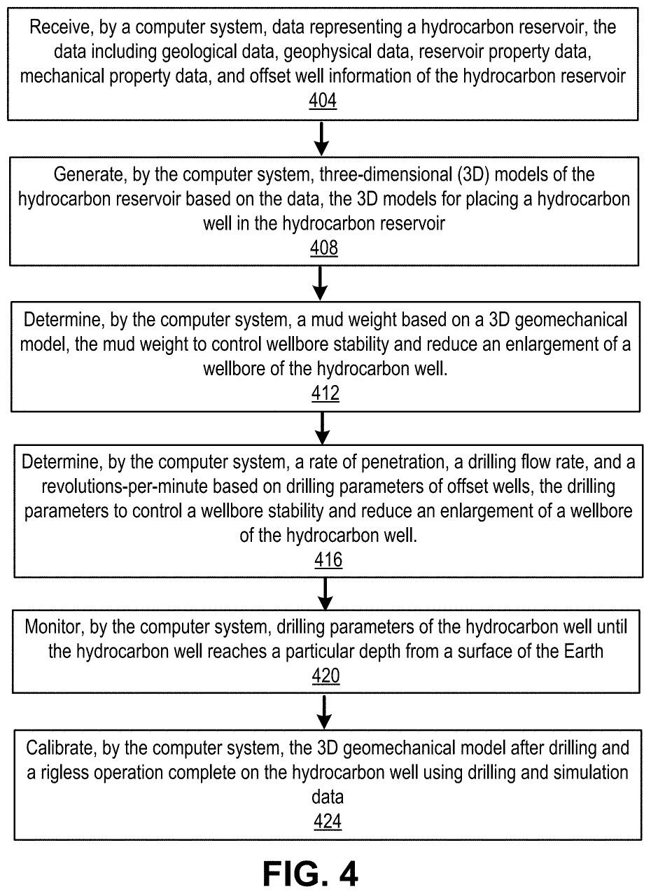

FIG. 2 illustrates three-dimensional (3D) models generated by the computer system, described in more detail with reference to FIG. 4. The 3D models include a 3D geomechanical model, a reservoir property model, and a mechanical property model. In some implementations the 3D geomechanical model includes a distribution of a geomechanical quality index (including reservoir properties and mechanical properties). The reservoir property model includes mainly porosity and permeability. The mechanical property model includes mainly effective stress of the hydrocarbon reservoir across a 3D space.

In FIG. 2, the computer system can discern a general trend of increasing geomechanical quality index from Zone I to Zone II to Zone III. Zone I, illustrated in FIG. 2, has a lower geomechanical quality index, lower reservoir properties, and a higher mechanical stress. Zone II has a higher geomechanical quality index, higher reservoir properties, and a lower mechanical stress. From a field operation perspective, Zone I can be less successful for production, drilling and completion. Zone II has a higher likelihood of success for production, drilling and completion (“sweet spot”). Zone III will likely need more effort to improve well completion.

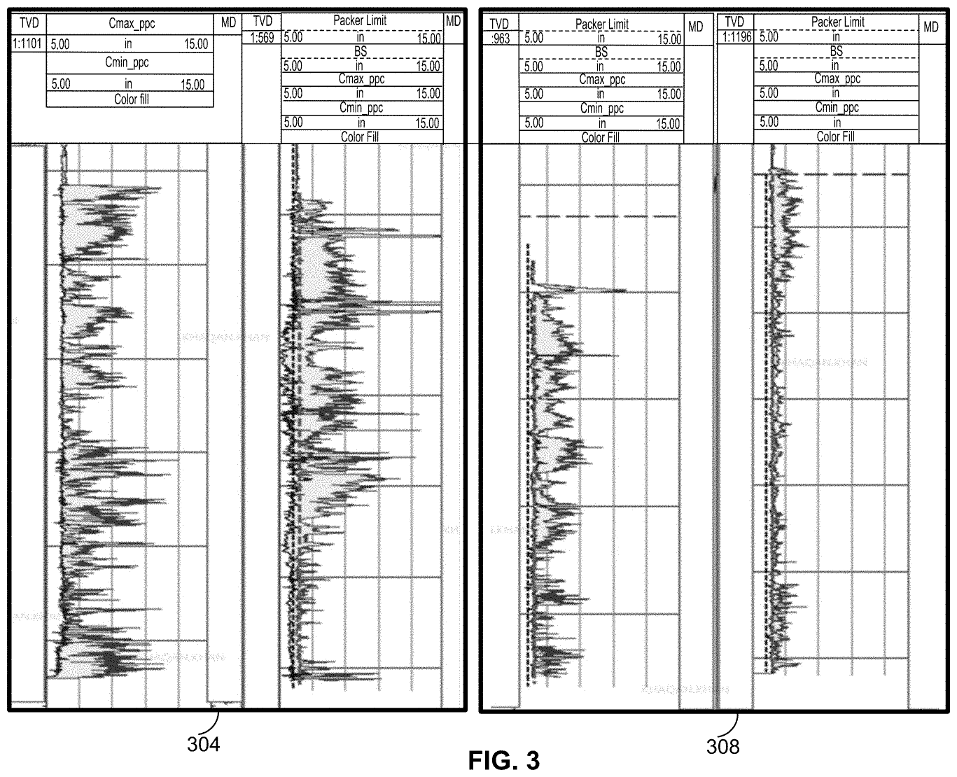

FIG. 3 compares hole conditions with and without using wellbore quality improvement. In experiments, a geomechanical analysis was performed using the embodiments described with reference to FIGS. 1 and 2. A pre-drill 3D geomechanical model was generated using offset well data. From the 3D geomechanical model, a mud weight was determined. The hydrocarbon wells were monitored in real time using LWD logs to assess hole conditions. The box 304 shows the resulting hole conditions (using multi-arm caliper data) for hydrocarbon wells drilled without using the implementations described with reference to FIGS. 1 and 2. The box 308 shows the resulting hole conditions (using multi-arm caliper data) for hydrocarbon wells drilled using the implementations described with reference to FIGS. 1 and 2. If the hole conditions needed repair, the computer system made changes to the mud weight and drilling parameters to keep the wellbore stable. A post-drill analysis of the hole conditions were performed, and the wellbore conformance was monitored (using openhole caliper logs data) against the requirements for completion.

FIG. 4 illustrates a process for wellbore quality improvement. The process is described in greater detail with reference to FIG. 1. In some implementations the process of FIG. 4 is performed by a computer system.

The computer system receives (404) data representing a hydrocarbon reservoir. The data includes a surface location, geological data, geophysical data, reservoir property data, mechanical property data, and offset well information of the hydrocarbon reservoir. Particular functions of the hydrocarbon reservoir management, reservoir characterization, drilling engineering, and production engineering are performed, and parameters for drilling a new hydrocarbon well are determined. For example, steps for planning the hydrocarbon well can be performed, including a review of the surface location of the hydrocarbon reservoir and offset wells in terms of development.

The computer system generates (408) 3D models of the hydrocarbon reservoir based on the data. For example, the computer system generates a 3D reservoir property model of the hydrocarbon reservoir based on the reservoir property data. The computer system generates a 3D mechanical property model of the hydrocarbon reservoir based on the mechanical property data. The computer system generates a 3D geomechanical model for identifying a good zone (sweet spot) for drilling and stimulation. The 3D geomechanical model is generated for placing a hydrocarbon well in the hydrocarbon reservoir. An example 3D geomechanical model is illustrated and described in more detail with reference to FIG. 2. The 3D geomechanical model is used to improve the placement of a hydrocarbon well in the hydrocarbon reservoir. For example, the gas saturation, reservoir pressure, and stress are used to predict issues or risks that can arise while drilling or stimulation of the hydrocarbon well, such as shallow picks, uncertain formation dips, or washouts.

The computer system determines (412) a mud weight based on the 3D geomechanical model. The mud weight is determined to control wellbore stability and reduce an enlargement of a wellbore of the hydrocarbon well. Mud weight refers to a density of drilling fluid and is measured in pounds per gallon (ppg) or pound cubic feet (pcf). For example, a mud weight used can be 22 or 23 ppg. The determined mud weight is used to reduce an enlargement of a wellbore of the hydrocarbon well.

The computer system determines (416) a rate of penetration (ROP), a drilling flow rate, and a revolutions-per-minute (RPM) based on drilling parameters of offset wells. The drilling parameters are to control the wellbore stability and reduce the enlargement of the wellbore of the hydrocarbon well.

The computer system monitors (420) drilling parameters of the hydrocarbon well until the hydrocarbon well reaches a particular depth from a surface of the Earth. The drilling parameters (surface RPM and mud flow rates) reduce post-drilling disturbance to the wellbore wall. A particular mud flow rate can also be required for carrying drill cuttings to the surface. The methods to address wellbore stability described here can have three main implementations, each allowing a different level of hole enlargement. The three implementations are described in more detail with reference to FIG. 1. The computer system performs a rigless operation on the hydrocarbon well. Rigless operation refers to an intervention operation conducted using equipment and support facilities without requiring a rig over the wellbore. The rigless site can include coiled tubing or a slickline. The coiled tubing refers to a continuous length of pipe wound on a spool that is straightened prior to pushing into the wellbore and rewound to coil the pipe back onto the spool. The slickline refers to a nonelectric cable used for selective placement and retrieval of wellbore hardware, such as plugs, gauges, or valves.

The computer system calibrates (424) the 3D geomechanical model after drilling and the rigless operation complete on the hydrocarbon well using drilling and simulation data.

The methods described can be performed in any sequence and in any combination, and the components of respective embodiments can be combined in any manner. The machine-implemented operations described above can be implemented by a computer system that includes programmable circuitry configured by software or firmware, or a special-purpose circuit, or a combination of such forms. Such a special-purpose circuit can be in the form of, for example, one or more application-specific integrated circuits (ASICs), programmable logic devices (PLDs), field-programmable gate arrays (FPGAs), or system-on-a-chip systems (SOCs).

Software or firmware to implement the techniques introduced here can be stored on a non-transitory machine-readable storage medium and executed by one or more general-purpose or special-purpose programmable microprocessors. A machine-readable medium, as the term is used, includes any mechanism that can store information in a form accessible by a machine (a machine can be, for example, a computer, network device, cellular phone, personal digital assistant (PDA), manufacturing tool, or any device with one or more processors). For example, a machine-accessible medium includes recordable or non-recordable media (RAM or ROM, magnetic disk storage media, optical storage media, or flash memory devices).

The term “logic,” as used herein, means: i) special-purpose hardwired circuitry, such as one or more application-specific integrated circuits (ASICs), programmable logic devices (PLDs), field programmable gate arrays (FPGAs), or other similar device(s); ii) programmable circuitry programmed with software and/or firmware, such as one or more programmed general-purpose microprocessors, digital signal processors (DSPs) or microcontrollers, system-on-a-chip systems (SOCs), or other similar device(s); or iii) a combination of the forms mentioned in i) and ii).

What is claimed is:

1. A method comprising:
receiving, by a computer system, data representing a hydrocarbon reservoir, the data comprising a surface location, reservoir property data, mechanical property data, and offset well information of the hydrocarbon reservoir;
generating, by the computer system, a three-dimensional (3D) geomechanical model of the hydrocarbon reservoir based on the data, the 3D geomechanical model for identifying a sweet spot in the hydrocarbon reservoir for drilling, stimulation, and placing a hydrocarbon well in the sweet spot;
determining, by the computer system, drilling parameters based on the 3D geomechanical model and the offset well information, the drilling parameters to reduce an enlargement of a wellbore of the hydrocarbon well;
monitoring, by the computer system, the drilling parameters until the hydrocarbon well reaches a particular depth from a surface of the Earth; and
performing, by the computer system, a rigless operation on the hydrocarbon well.

2. The method of claim 1, wherein the 3D geomechanical model comprises a distribution of porosity, permeability, gas saturation, mechanical properties, and reservoir stress of the hydrocarbon reservoir across a 3D space.

3. The method of claim 1, wherein the drilling parameters comprise a mud weight, a mud flow rate, a rate of penetration, and a drilling revolutions-per-minute based on the 3D geomechanical model.

4. The method of claim 1, further comprising:
responsive to determining, by the computer system, that the rigless operation has completed, calibrating, by the computer system, the 3D geomechanical model based on second data obtained from the hydrocarbon well.

5. The method of claim 1, further comprising determining, by the computer, system a trajectory of the hydrocarbon well and an azimuth of the hydrocarbon well based on the 3D geomechanical model.

6. A non-transitory computer-readable storage medium storing instructions executable by one or more computer processors, the instructions when executed by the one or more computer processors cause the one or more computer processors to:
receive data representing a hydrocarbon reservoir, the data comprising a surface location, reservoir property data, mechanical property data, and offset well information of the hydrocarbon reservoir;
generate a 3D geomechanical model of the hydrocarbon reservoir based on the data, the 3D geomechanical model for identifying a sweet spot in the hydrocarbon reservoir for drilling, stimulation, and placing a hydrocarbon well in the sweet spot;
determine drilling parameters based on the 3D geomechanical model and the offset well information, the drilling parameters to reduce an enlargement of a wellbore of the hydrocarbon well;
monitor the drilling parameters of the hydrocarbon well until the hydrocarbon well reaches a particular depth from a surface of the Earth; and
perform a rigless operation on the hydrocarbon well.

7. The non-transitory computer-readable storage medium of claim 6, wherein the 3D geomechanical model comprises a distribution of porosity, permeability, gas saturation, mechanical properties, and reservoir stress of the hydrocarbon reservoir across a 3D space.

8. The non-transitory computer-readable storage medium of claim 6, wherein the drilling parameters comprise a mud weight, a mud flow rate, a rate of penetration, and a drilling revolutions-per-minute based on the 3D geomechanical model.

9. The non-transitory computer-readable storage medium of claim 6, the instructions further causing the one or more computer processors to:
responsive to determining that the rigless operation has completed, calibrate the 3D geomechanical model based on second data obtained from the hydrocarbon well.

10. The non-transitory computer-readable storage medium of claim 6, the instructions further causing the one or more computer processors to determine a trajectory of the hydrocarbon well and an azimuth of the hydrocarbon well based on the 3D geomechanical model.

11. A computer system comprising:
one or more computer processors; and
a non-transitory computer-readable storage medium storing instructions executable by the one or more computer processors, the instructions when executed by the one or more computer processors cause the one or more computer processors to:
receive data representing a hydrocarbon reservoir, the data comprising a surface location, reservoir property data, mechanical property data, and offset well information of the hydrocarbon reservoir;
generate a 3D geomechanical model of the hydrocarbon reservoir based on the data, the 3D geomechanical model for identifying a sweet spot in the hydrocarbon reservoir for drilling, stimulation, and placing a hydrocarbon well in the sweet spot;
determine drilling parameters based on the 3D geomechanical model and the offset well information, the drilling parameters to reduce an enlargement of a wellbore of the hydrocarbon well;
monitor the drilling parameters of the hydrocarbon well until the hydrocarbon well reaches a particular depth from a surface of the Earth; and
perform a rigless operation on the hydrocarbon well.

12. The system of claim 11, wherein the 3D geomechanical model comprises a distribution of porosity, permeability, gas saturation, mechanical properties, and reservoir stress of the hydrocarbon reservoir across a 3D space.

13. The system of claim 11, wherein the drilling parameters comprise a mud weight, a mud flow rate, a rate of penetration, and a drilling revolutions-per-minute based on the 3D geomechanical model.

14. The system of claim 11, the instructions further causing the one or more computer processors to:
responsive to determining that the rigless operation has completed, calibrate the 3D geomechanical model based on second data obtained from the hydrocarbon well.

15. The system of claim 11, the instructions further causing the one or more computer processors to determine a trajectory of the hydrocarbon well and an azimuth of the hydrocarbon well based on the 3D geomechanical model.
